(19) United States
(12) Patent Application Publication
(10) Pub. No.: US 2026/0047124 A1
(43) Pub. Date: Feb. 12, 2026

(54) SEMICONDUCTOR DEVICE

(71) Applicants: Kabushiki Kaisha Toshiba, Kawasaki-shi (JP); Toshiba Electronic Devices & Storage Corporation, Kawasaki-shi (JP)

(72) Inventors: Toru SUGIYAMA, Musashino Tokyo (JP); Akira YOSHIOKA, Yokohama Kanagawa (JP); Hitoshi KOBAYASHI, Yamato Kanagawa (JP); Yasuhiro ISOBE, Narashino Chiba (JP); Yasunobu SAITO, Inagi Tokyo (JP); Takao NODA, Yokohama Kanagawa (JP); Hideki SEKIGUCHI, Yokohama Kanagawa (JP); Yorito KAKIUCHI, Yokohama Kanagawa (JP); Tetsuya OHNO, Yokohama Kanagawa (JP); Kazuki KIYOHARA, Yamato Kanagawa (JP); Shugo NISHIMURA, Yokohama Kanagawa (JP); Shintaro UEDA, Yokohama Kanagawa (JP)

(21) Appl. No.: 19/359,070

(22) Filed: Oct. 15, 2025

Related U.S. Application Data
(63) Continuation of application No. PCT/JP2023/034317, filed on Sep. 21, 2023.

(51) Int. Cl. H10D 30/47; H10D 62/10; H10D 62/824; H10D 64/00; H10D 64/27; H10D 64/68

(52) U.S. Cl. CPC H10D 30/475; H10D 62/102; H10D 62/824; H10D 64/112; H10D 64/516; H10D 64/518; H10D 64/685; H10D 64/693

(57) ABSTRACT

According to one embodiment, a semiconductor device includes a semiconductor layer, first and second electrodes, first to fourth insulating layer, a gate electrode, and a first field plate electrode. The gate electrode is located on the first insulating layer. The gate electrode includes first and second parts. A lower surface of the second part is positioned higher than that of the first part. The second insulating layer is located between the first insulating layer and the second part. The first and second insulating layers contain a first insulating material. The third insulating layer is located on the gate electrode and on the first and second insulating layers. The first field plate electrode is located on the third insulating layer. The fourth insulating layer is located on the third insulating layer and the first field plate electrode. The third and fourth insulating layers contain a second insulating material.

### CROSS-REFERENCE TO RELATED APPLICATIONS

This is a continuation application of International Patent Application PCT/JP2023/034317, filed on Sep. 21, 2023.

### FIELD Embodiments described herein relate generally to a semiconductor device.

### BACKGROUND

There is a semiconductor device that includes gallium nitride. Technology that can suppress the occurrence of dielectric breakdown in such a semiconductor device is desirable.

### BRIEF DESCRIPTION OF THE DRAWINGS

FIG. 1 is a cross-sectional view showing a portion of a semiconductor device according to an embodiment;

FIG. 2 is a cross-sectional view showing a portion of a semiconductor device according to a reference example;

FIG. 3 is a cross-sectional view showing a portion of a semiconductor device according to a reference example;

FIG. 4 is a graph showing characteristics of the semiconductor devices according to the reference examples;

FIGS. 5A and 5B are schematic views showing characteristics of the semiconductor devices according to the reference examples; and

FIG. 6 is a cross-sectional view showing a portion of a semiconductor device according to a modification of the embodiment.

### DETAILED DESCRIPTION

According to one embodiment, a semiconductor device includes a semiconductor layer, a first electrode, a second electrode, a first insulating layer, a gate electrode, a second insulating layer, a third insulating layer, a first field plate electrode, and a fourth insulating layer. The semiconductor layer contains gallium nitride. The first electrode is located on a portion of the semiconductor layer. The second electrode is separated from the first electrode on another portion of the semiconductor layer. The first insulating layer is located on the semiconductor layer. The first insulating layer is positioned between the first electrode and the second electrode in a first direction. The first direction is from the first electrode toward the second electrode. The first insulating layer contains a first insulating material. The gate electrode is located on the first insulating layer. The gate electrode includes a first part and a second part. A position in the first direction of the second part is between a position in the first direction of the first part and a position in the first direction of the second electrode. A lower surface of the second part is positioned higher than a lower surface of the first part in a second direction perpendicular to the first direction. The second insulating layer is located between the first insulating layer and the second part in the second direction, the second insulating layer containing the first insulating material. The third insulating layer is located on the gate electrode, on the first insulating layer, and on the second insulating layer. The third insulating layer contains a second insulating material. The first field plate electrode is located on the third insulating layer. The first field plate electrode is electrically connected to the first electrode. A position in the first direction of the first field plate electrode is between a position in the first direction of the gate electrode and the position in the first direction of the second electrode. The fourth insulating layer is located on the third insulating layer and the first field plate electrode. The fourth insulating layer contains the second insulating material.

Embodiments of the invention will now be described with reference to the drawings. The drawings are schematic or conceptual; and the relationships between the thicknesses and widths of portions, the proportions of sizes between portions, etc., are not necessarily the same as the actual values thereof. The dimensions and/or the proportions may be illustrated differently between the drawings, even i n the case where the same portion is illustrated. In the drawings and the specification of the application, components similar to those described thereinabove are marked with like reference numerals, and a detailed description is omitted as appropriate.

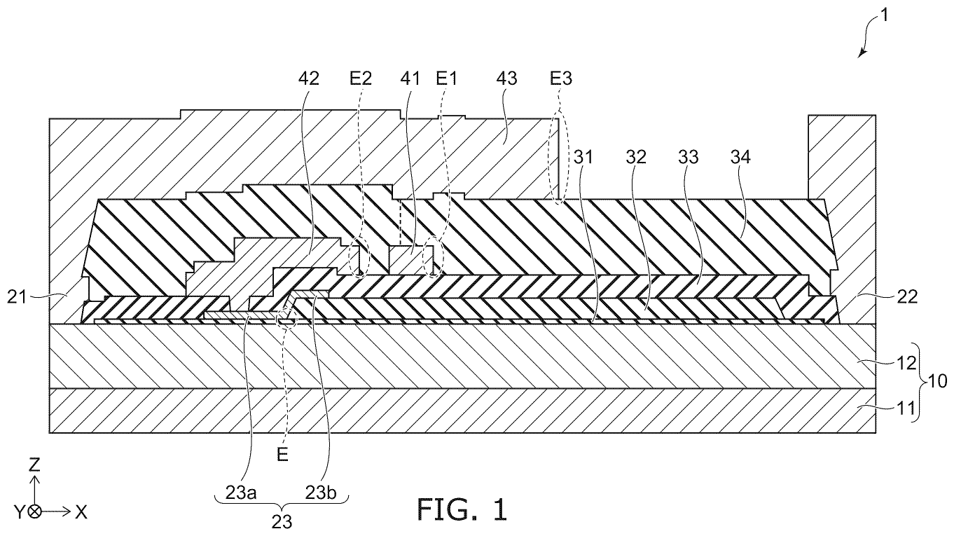

FIG. 1 is a cross-sectional view showing a portion of a semiconductor device according to an embodiment.

The semiconductor device 1 according to the embodiment is a MOSFET. As shown in FIG. 1, the semiconductor device 1 according to the embodiment includes a semiconductor layer 10, a source electrode 21 (a first electrode), a drain electrode 22 (a second electrode), a gate electrode 23, a first insulating layer 31, a second insulating layer 32, a third insulating layer 33, and a fourth insulating layer 34. The semiconductor device 1 also includes a field plate electrode (a FP electrode). Specifically, the semiconductor device 1 includes a first FP electrode 41, a second FP electrode 42, and a third FP electrode 43.

An XYZ orthogonal coordinate system is used in the description of embodiments. The direction from the source electrode 21 toward the drain electrode 22 is referred to as an X-direction (a first direction). The direction from the semiconductor layer 10 toward the source electrode 21 that is perpendicular to the X-direction is referred to as a Z-direction (a second direction). A direction perpendicular to the X-direction and Z-direction is referred to as a Y-direction. In the description, the direction from the semiconductor layer 10 toward the source electrode 21 is referred to as “up” or “above”, and the opposite direction is referred to as “down” or “below”. These directions are based on the relative positional relationship between the semiconductor layer 10 and the source electrode 21, and are independent of the direction of gravity.

The semiconductor layer 10 includes gallium nitride. For example, the semiconductor layer 10 includes a first semiconductor region 11 and a second semiconductor region 12. The first semiconductor region 11 includes Alₓ₁Ga₁₋ₓ₁N (0≤x1<1). The second semiconductor region 12 includes Alₓ₂Ga₁₋ₓ₂N (0<x2<1 and x1<x2). As an example, the first semiconductor region 11 is a GaN layer that substantially does not include Al; and the second semiconductor region 12 is an AlGaN layer. The semiconductor layer 10 may be located on a semiconductor substrate, a buffer layer, etc., which are not illustrated.

The source electrode 21 is located on a portion of the semiconductor layer 10. The drain electrode 22 is located on another portion of the semiconductor layer 10. The drain electrode 22 is separated from the source electrode 21 in the X-direction. The source electrode 21 and the drain electrode 22 are electrically connected to the second semiconductor region 12 of the semiconductor layer 10.

The first insulating layer 31 is located on the semiconductor layer 10 and positioned between the source electrode 21 and the drain electrode 22. For example, the first insulating layer 31 is separated from the source electrode 21 and the drain electrode 22 in the X-direction. The first insulating layer 31 includes a first insulating material.

The gate electrode 23 is located on the first insulating layer 31. The first insulating layer 31 functions as a gate insulating layer. The gate electrode 23 includes a first part 23a and a second part 23b. The X-direction position of the second part 23b is between the X-direction position of the first part 23a and the X-direction position of the drain electrode 22. In other words, the second part 23b is positioned between the first part 23a and the drain electrode 22 in the X-direction when the semiconductor device 1 is viewed along the Z-direction. The lower surface of the second part 23b is positioned higher than the lower surface of the first part 23a.

The second insulating layer 32 is located between the first insulating layer 31 and the second part 23b. The first part 23a is aligned with the second insulating layer 32 in the X-direction. As illustrated, the second insulating layer 32 also may be located in a region positioned at the drain electrode 22 side of the second part 23b. The second insulating layer 32 includes the first insulating material. The thickness (the dimension in the Z-direction) of the second insulating layer 32 is greater than the thickness of the first insulating layer 31.

The third insulating layer 33 is located on the gate electrode 23, the first insulating layer 31, and the second insulating layer 32. One X-direction end of the third insulating layer 33 is positioned between the source electrode 21 and the first insulating layer 31 and contacts the semiconductor layer 10 and the source electrode 21. The other X-direction end of the third insulating layer 33 is positioned between the drain electrode 22 and the first insulating layer 31 and contacts the semiconductor layer 10 and the drain electrode 22. The third insulating layer 33 includes a second insulating material. The second insulating material is different from the first insulating material.

The first FP electrode 41 is located on the third insulating layer 33. The first FP electrode 41 is connected to the source electrode 21 at a part that is not illustrated; and an electrical connection is formed between the source electrode 21 and the first FP electrode 41 as illustrated by a broken line. The X-direction position of the first FP electrode 41 is between the X-direction position of the gate electrode 23 and the X-direction position of the drain electrode 22.

The second FP electrode 42 is located on the third insulating layer 33 and is positioned on the gate electrode 23. The second FP electrode 42 is electrically connected to the gate electrode 23. An end E2 in the X-direction of the second FP electrode 42 is positioned at the drain electrode 22 side of the gate electrode 23. In other words, the X-direction position of the end E2 is between the X-direction position of the gate electrode 23 and the X-direction position of the drain electrode 22.

The fourth insulating layer 34 is located on the third insulating layer 33, the first FP electrode 41, and the second FP electrode 42. The fourth insulating layer 34 includes the second insulating material. The thickness of the fourth insulating layer 34 is greater than the thickness of the third insulating layer 33.

The third FP electrode 43 is located on the fourth insulating layer 34 and positioned on the first FP electrode 41 and the second FP electrode 42. The third FP electrode 43 is electrically connected to the source electrode 21. An end E3 in the X-direction of the third FP electrode 43 is positioned at the drain electrode 22 side of the first FP electrode 41. In other words, the X-direction position of the end E3 is between the X-direction position of the first FP electrode 41 and the X-direction position of the drain electrode 22.

Examples of materials of the components are as follows. The source electrode 21, the drain electrode 22, the gate electrode 23, the first FP electrode 41, the second FP electrode 42, and the third FP electrode 43 include metal materials such as titanium, copper, aluminum, etc. The first insulating material that is included in the first and second insulating layers 31 and 32 is one selected from the group consisting of silicon nitride, silicon oxide, and silicon oxynitride. The second insulating material that is included in the third and fourth insulating layers 33 and 34 is another one selected from the group consisting of silicon nitride, silicon oxide, and silicon oxynitride. For example, the relative dielectric constant of the first insulating material is greater than the relative dielectric constant of the second insulating material.

Operations of the semiconductor device 1 will now be described. A two-dimensional electron gas (2DEG) is generated at the vicinity of the interface between the first semiconductor region 11 and the second semiconductor region 12. When a voltage that is positive with respect to the source electrode 21 is applied to the drain electrode 22, electrons that are included in the two-dimensional electron gas move from the source electrode 21 to the drain electrode 22; and a current flows between the source electrode 21 and the drain electrode 22. When a negative voltage is applied to the gate electrode 23, the electrons in the region below the gate electrode 23 are ejected by the potential difference between the semiconductor layer 10 and the gate electrode 23; and the region is depleted. The current flowing in the semiconductor device 1 is stopped thereby.

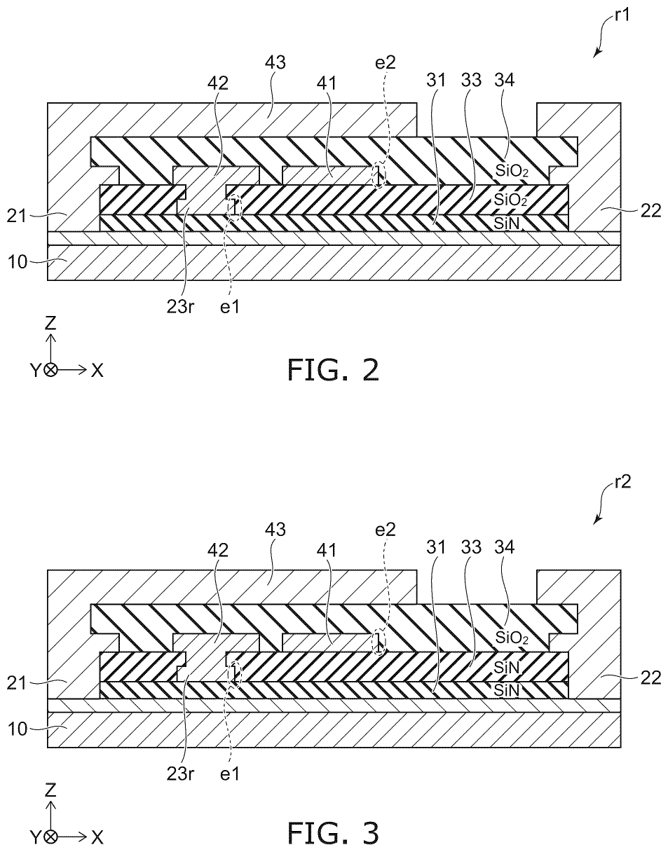

FIGS. 2 and 3 are cross-sectional views showing portions of semiconductor devices according to reference examples.

Advantages of the embodiment of the invention will now be described with reference to the semiconductor devices according to the reference examples. Semiconductor devices r1 and r2 shown in FIGS. 2 and 3 include the semiconductor layer 10, the source electrode 21, the drain electrode 22, a gate electrode 23r, the first insulating layer 31, the third insulating layer 33, the fourth insulating layer 34, the first FP electrode 41, the second FP electrode 42, and the third FP electrode 43.

The second insulating layer 32 is not included in the semiconductor devices r1 and r2. A gate electrode 23r differs from the gate electrode 23 in that the gate electrode 23r does not include the second part 23b. In the semiconductor device r1, the first insulating layer 31 includes silicon nitride; and the third insulating layer 33 and the fourth insulating layer 34 include silicon oxide. In the semiconductor device r2, the first insulating layer 31 and the third insulating layer 33 include silicon nitride; and the fourth insulating layer 34 includes silicon oxide. The gate electrode 23r includes an end e1 in the X-direction. The first FP electrode 41 includes an end e2 in the X-direction.

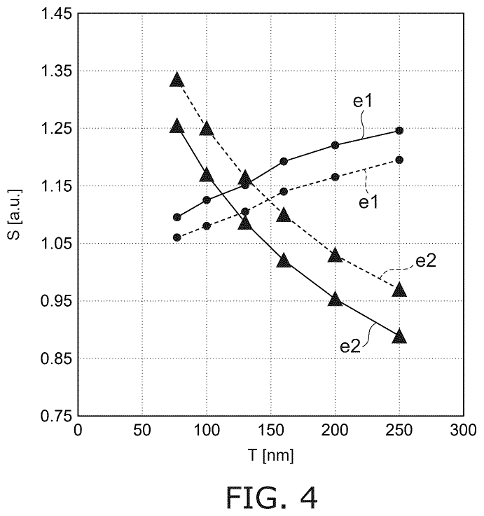

FIG. 4 is a graph showing characteristics of the semiconductor devices according to the reference examples.

In FIG. 4, the horizontal axis is a thickness T of the third insulating layer 33; and the vertical axis is an electric field intensity S. The circular marks illustrate the electric field intensity at the lower end vicinity of the end e1. The triangular marks illustrate the electric field intensity at the lower end vicinity of the end e2. The solid lines illustrate characteristics of the semiconductor device r1; and the broken lines illustrate characteristics of the semiconductor device r2. In FIG. 4, the electric field intensity S is a relative ratio.

The first insulating layer 31 contacts the semiconductor layer 10. An insulating material that can suppress reactions with the semiconductor layer 10 is selected as the material of the first insulating layer 31. As an example, when the oxygen concentration of the first insulating layer 31 is low, reactions between the first insulating layer 31 and the semiconductor layer 10 can be suppressed. It is therefore favorable for the first insulating layer 31 to be a silicon oxynitride layer having a low oxygen concentration, or a silicon nitride layer that substantially does not include oxygen.

The first FP electrode 41 is provided to relax the electric field intensity at the end e1 vicinity of the gate electrode 23r. The first FP electrode 41 is located on the third insulating layer 33. The Z-direction distance between the semiconductor layer 10 and the first FP electrode 41 is greater than the Z-direction distance between the semiconductor layer 10 and the gate electrode 23. Therefore, the electric field intensity at the end e2 vicinity of the first FP electrode 41 may be greater than the electric field intensity at the end e1 vicinity of the gate electrode 23r. On the other hand, when the electric field intensity at the end e2 vicinity is high, the insulative properties of the third insulating layer 33 may degrade over time, and the breakdown immunity of the semiconductor device may be reduced. Accordingly, an insulating material that can increase the long-term reliability is selected as the material of the third insulating layer 33. As an example, when the nitrogen concentration of the third insulating layer 33 is low, degradation of the insulative properties of the third insulating layer 33 over time can be suppressed, and the reduction of the breakdown immunity of the semiconductor device can be suppressed. It is therefore favorable for the third insulating layer 33 to be a silicon oxynitride layer having a low nitrogen concentration, or a silicon oxide layer that substantially does not include nitrogen.

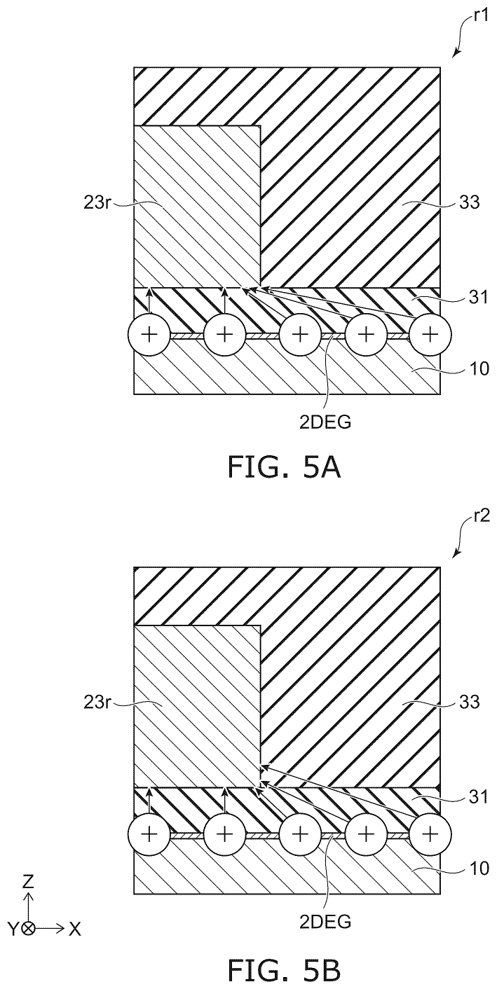

FIGS. 5A and 5B are schematic views showing characteristics of the semiconductor devices according to the reference examples.

The relative dielectric constant of silicon nitride is greater than the relative dielectric constant of silicon oxide. In the semiconductor device r1, in which the first insulating layer 31 includes silicon nitride and the third insulating layer 33 includes silicon oxide, the lines of electric force are distributed to avoid the third insulating layer 33 as shown in FIG. 5A. Therefore, the electric field intensity tends to increase at the end e1 vicinity; and the likelihood of dielectric breakdown of the first insulating layer 31 is higher.

On the other hand, in the semiconductor device r2, in which the third insulating layer 33 includes silicon nitride, the bias of the lines of electric force caused by the difference between the relative dielectric constant of the first insulating layer 31 and the relative dielectric constant of the third insulating layer 33 is relaxed as shown in FIG. 5B. It can be seen from comparing the solid line plot of circles and the broken line plot of circles in FIG. 4 that the electric field intensity at the end e1 vicinity can be relaxed.

On the other hand, in the semiconductor device r2, the relative dielectric constant of the silicon nitride included in the third insulating layer 33 is greater than the relative dielectric constant of the silicon oxide included in the fourth insulating layer 34. Therefore, the lines of electric force are distributed to avoid the fourth insulating layer 34 at the lower end vicinity of the end e2. It can be seen from comparing the solid line plot of triangles and the broken line plot of triangles that the electric field intensity at the end e2 vicinity is higher. Also, the long-term reliability of the semiconductor device may be degraded by the increased nitrogen concentration of the third insulating layer 33.

For these problems, as shown in FIG. 1, the semiconductor device 1 according to the embodiment includes the second insulating layer 32. The gate electrode 23 includes the first part 23a and the second part 23b. The second insulating layer 32 is located between the first insulating layer 31 and the second part 23b. An end E in the X-direction of the first part 23a contacts the first and second insulating layers 31 and 32. The first insulating layer 31 and the second insulating layer 32 include a common first insulating material. Therefore, the relative dielectric constant of the second insulating layer 32 is substantially equal to the relative dielectric constant of the first insulating layer 31. By including the second insulating layer 32, the electric field intensity at the end E vicinity can be relaxed. The occurrence of dielectric breakdown of the first insulating layer 31 can be suppressed thereby.

The first FP electrode 41 is located on the third insulating layer 33; and the fourth insulating layer 34 covers the first FP electrode 41. The lower end of an end E1 of the first FP electrode 41 contacts the third and fourth insulating layers 33 and 34. The third insulating layer 33 and the fourth insulating layer 34 include a common second insulating material. Therefore, the relative dielectric constant of the fourth insulating layer 34 is substantially equal to the relative dielectric constant of the third insulating layer 33. As a result, the electric field intensity at the vicinity of the end E1 in the X-direction of the first FP electrode 41 can be relaxed; and the occurrence of dielectric breakdown of the third insulating layer 33 can be suppressed.

According to the embodiment, the first insulating material and the second insulating material each can be optimized. For example, as the first insulating material, silicon oxynitride that has a lower oxygen concentration than the second insulating material is used, or silicon nitride that substantially does not include oxygen is used. As a result, reactions with the semiconductor layer 10 of the first insulating material included in the first insulating layer 31 can be suppressed. As the second insulating material, silicon oxynitride that has a lower nitrogen concentration than the first insulating material is used, or silicon oxide that substantially does not include nitrogen is used. As a result, the long-term reliability of the third insulating layer 33 can be increased, and the reduction of the breakdown immunity of the semiconductor device 1 over time can be suppressed.

According to the semiconductor device 1 according to the embodiment, the occurrence of dielectric breakdown of the first insulating layer 31 can be suppressed while suppressing a reduction of the breakdown immunity over time.

It is favorable for the semiconductor device 1 to include at least one of the second FP electrode 42 or the third FP electrode 43. As a result, the electric field intensity at the end E vicinity or the electric field intensity at the end E1 vicinity can be further reduced.

A portion of the third insulating layer 33 is located between the first insulating layer 31 and the drain electrode 22 in the X-direction and contacts the semiconductor layer 10. The portion of the third insulating layer 33 is positioned between the semiconductor layer 10 and a portion of the drain electrode 22 in the Z-direction. In other words, the third insulating layer 33 that has a low nitrogen concentration and does not easily trap electrons is located under a portion of the drain electrode 22. The generation of electron traps under the portion of the drain electrode 22 can be suppressed thereby. For example, electron traps when a high voltage is applied to the drain electrode are suppressed, and an increase of the on-resistance (a so-called collapse) is suppressed.

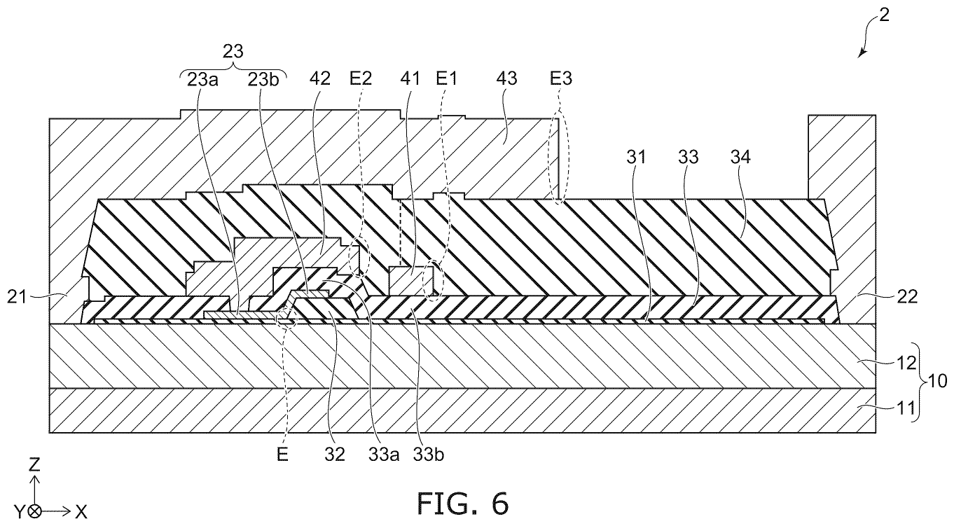

FIG. 6 is a cross-sectional view showing a portion of a semiconductor device according to a modification of the embodiment.

Compared to the semiconductor device 1, the first FP electrode 41 is located at a lower position in the semiconductor device 2 according to the modification shown in FIG. 6. Specifically, the second insulating layer 32 is located between the first insulating layer 31 and the second part 23b and is not located directly under the first FP electrode 41. Compared to the semiconductor device 1, the first FP electrode 41 in the semiconductor device 2 is positioned lower by the amount of the thickness of the second insulating layer 32.

For example, the third insulating layer 33 includes a first insulating part 33a and a second insulating part 33b. The first insulating part 33a is positioned on the second part 23b. The second insulating part 33b is positioned under the first FP electrode 41. The upper surface of the second insulating part 33b is positioned lower than the upper surface of the first insulating part 33a. The lower surface of the first FP electrode 41 is positioned lower than the lower surface of the end E2 of the second FP electrode 42.

In the semiconductor devices 1 and 2, the insulating material that is included in the second insulating layer 32 is different from the insulating material included in the third insulating layer 33. In other words, the relative dielectric constant of the second insulating layer 32 is different from the relative dielectric constant of the third insulating layer 33. Therefore, there is a possibility that the electric field intensity may increase at the vicinity of the X-direction end of the second part 23b, and dielectric breakdown of the second insulating layer 32 may occur. However, according to the semiconductor device 2, compared to the semiconductor device 1, the first FP electrode 41 is located at a lower position. As a result, the electric field intensity at the end vicinity of the second part 23b can be reduced, and the occurrence of dielectric breakdown of the second insulating layer 32 can be suppressed.

According to the semiconductor device 2 according to the modification, compared to the semiconductor device 1, the occurrence of dielectric breakdown can be further suppressed.

The embodiment of the invention includes the following features.

### Feature 1

A semiconductor device, including:
a semiconductor layer including gallium nitride;
a first electrode located on a portion of the semiconductor layer;
a second electrode separated from the first electrode on another portion of the semiconductor layer;
a first insulating layer located on the semiconductor layer, the first insulating layer being positioned between the first electrode and the second electrode in a first direction, the first direction being from the first electrode toward the second electrode, the first insulating layer including a first insulating material;
a gate electrode located on the first insulating layer, the gate electrode including a first part and a second part, a position in the first direction of the second part being between a position in the first direction of the first part and a position in the first direction of the second electrode, a lower surface of the second part being positioned higher than a lower surface of the first part;
a second insulating layer located between the first insulating layer and the second part, the second insulating layer including the first insulating material;
a third insulating layer located on the gate electrode, on the first insulating layer, and on the second insulating layer, the third insulating layer including a second insulating material;
a first field plate electrode located on the third insulating layer, a position in the first direction of the first field plate electrode being between a position in the first direction of the gate electrode and the position in the first direction of the second electrode, the first field plate electrode being electrically connected to the first electrode; and
a fourth insulating layer located on the third insulating layer and the first field plate electrode, the fourth insulating layer including the second insulating material.

### Feature 2

The device according to feature 1, in which
the third insulating layer includes:
   a first insulating part positioned on the second part; and
   a second insulating part positioned under the first field plate electrode, and
an upper surface of the second insulating part is positioned lower than an upper surface of the first insulating part.

### Feature 3

The device according to feature 1, further including:
a second field plate electrode located on the third insulating layer,
the second field plate electrode being electrically connected to the gate electrode,
a position in the first direction of a portion of the second field plate electrode being between the position in the first direction of the gate electrode and the position in the first direction of the first field plate electrode.

### Feature 4

The device according to feature 3, in which
a lower surface of the first field plate electrode is positioned lower than a lower surface of the portion of the second field plate electrode.

### Feature 5

The device according to any one of features 1 to 4, in which
a portion of the third insulating layer is located between the first insulating layer and the second electrode in the first direction and contacts the semiconductor layer.

### Feature 6

The device according to feature 5, in which
the portion of the third insulating layer is positioned between the semiconductor layer and a portion of the second electrode in a second direction, and
the second direction is perpendicular to the first direction.

### Feature 7

The device according to any one of features 1 to 6, in which
the first insulating material is silicon nitride, and
the second insulating material is silicon oxide.

### Feature 8

The device according to any one of features 1 to 7, in which
the first insulating material has a higher relative dielectric constant than the second insulating material.

### Feature 9

The device according to any one of features 1 to 8, in which
the second insulating layer is thicker than the first insulating layer, and
the fourth insulating layer is thicker than the third insulating layer.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention. Moreover, above-mentioned embodiments can be combined mutually and can be carried out.

What is claimed is:

1. A semiconductor device, comprising:
a semiconductor layer containing gallium nitride;
a first electrode located on a portion of the semiconductor layer;
a second electrode located on another portion of the semiconductor layer and separated from the first electrode;
a first insulating layer located on the semiconductor layer, the first insulating layer being positioned between the first electrode and the second electrode in a first direction, the first direction being from the first electrode toward the second electrode, the first insulating layer containing a first insulating material;
a gate electrode located on the first insulating layer, the gate electrode including a first part and a second part, a position in the first direction of the second part being between a position in the first direction of the first part and a position in the first direction of the second electrode, a lower surface of the second part being positioned higher than a lower surface of the first part in a second direction perpendicular to the first direction;
a second insulating layer located between the first insulating layer and the second part in the second direction, the second insulating layer containing the first insulating material;
a third insulating layer located on the gate electrode, on the first insulating layer, and on the second insulating layer, the third insulating layer containing a second insulating material;
a first field plate electrode located on the third insulating layer, a position in the first direction of the first field plate electrode being between a position in the first direction of the gate electrode and the position in the first direction of the second electrode, the first field plate electrode being electrically connected to the first electrode; and
a fourth insulating layer located on the third insulating layer and the first field plate electrode, the fourth insulating layer containing the second insulating material.

2. The device according to claim 1, wherein
the third insulating layer includes:
a first insulating part positioned on the second part of the gate electrode; and
a second insulating part positioned under the first field plate electrode, and
an upper surface of the second insulating part is positioned lower than an upper surface of the first insulating part in the second direction.

3. The device according to claim 1, further comprising:
a second field plate electrode located on the third insulating layer,
the second field plate electrode being electrically connected to the gate electrode,
a position in the first direction of a portion of the second field plate electrode being between the position in the first direction of the gate electrode and the position in the first direction of the first field plate electrode.

4. The device according to claim 3, wherein
a lower surface of the first field plate electrode is positioned lower than a lower surface of the portion of the second field plate electrode in the second direction.

5. The device according to claim 1, wherein
a portion of the third insulating layer is located between the first insulating layer and the second electrode in the first direction and contacts the semiconductor layer.

6. The device according to claim 5, wherein
the portion of the third insulating layer is positioned between the semiconductor layer and a portion of the second electrode in the second direction.

7. The device according to claim 1, wherein
the second insulating material has a lower nitrogen concentration than the first insulating material.

8. The device according to claim 1, wherein
the first insulating material is silicon nitride, and
the second insulating material is silicon oxide.

9. The device according to claim 1, wherein
the first insulating material has a higher relative dielectric constant than the second insulating material.

10. The device according to claim 1, wherein
the second insulating layer is thicker than the first insulating layer, and
the fourth insulating layer is thicker than the third insulating layer.

11. The device according to claim 1, wherein
a distance between the semiconductor layer and the first field plate electrode in the second direction is greater than a distance between the semiconductor layer and the gate electrode in the second direction.
